(19) United States
(12) Patent Application Publication
(10) Pub. No.: US 2024/0373592 A1
(43) Pub. Date: Nov. 7, 2024

(54) CYLINDRICAL AND DIAMOND-SHAPED EVAPORATIVE COOLERS USING HOLLOW FIBERS

(71) Applicant: 3M INNOVATIVE PROPERTIES COMPANY, St. Paul, MN (US)

(72) Inventors: Neeraj Sinai Borker, Minneapolis, MN (US); Garth V. Antila, Hudson, WI (US); Brinda B. Badri, Woodbury, MN (US); Steven D. Solomonson, Shoreview, MN (US); John P. Baetzold, North St. Paul, MN (US); Joseph A. Dunbar, Woodbury, MN (US); Abhay R. Joshi, Oakdale, MN (US)

(21) Appl. No.: 18/683,396

(22) PCT Filed: Sep. 8, 2022
(86) PCT No.: PCT/IB2022/058469

§ 371 Date: Feb. 13, 2024

Related U.S. Application Data
(60) Provisional application No. 63/242,611, filed on Sep. 10, 2021.
(60) Provisional application No. 63/284,253, filed on Nov. 30, 2021.

(51) Int. Cl. H05K 7/20

(52) U.S. Cl. CPC H05K 7/20336; H05K 7/20327; H05K 7/20827

(57) ABSTRACT

A unit for use in evaporative cooling includes a first capped frame and a second open frame opposite the first frame. Posts are located between and coupled to the first and second frames. A porous hollow fiber membrane extends around the posts between and coupled to the first and second frames to form an interior volume. The first and second frames are configured for flow of water between them via the membrane. The membrane is configured to transport the water between the first and second frames and to provide for air flow from the interior volume through the membrane for evaporative cooling. The cooling unit can have a rounded square or diamond-shaped cross-sectional shape.

### BACKGROUND

Evaporation is a cost and energy efficient way of cooling and is used for regulating temperatures in data centers, food processing plants, or office buildings. Currently, cellulosic pads are used to perform evaporative cooling on a large scale such as in a data center. Hot dry air is cooled by evaporating water flowing over the cellulosic pads yielding cool, humid air on the output. Large amounts of water are required for this type of cooling, and the media must be maintained either in a dry state or wet state to prevent degradation due to fouling or crystalline salt deposition. The humidity level of the air discharged into the data center can be controlled using louvers or dampers which direct the input air through only a portion of the media or completely around the media in a bypass duct. Accordingly, a need exists for an improved evaporative cooling system.

### SUMMARY

A unit for use in evaporative cooling includes a first capped frame and a second open frame opposite the first frame. A plurality of mechanical supports are located between and coupled to the first and second frames. A porous hollow fiber membrane extends around the supports between and coupled to the first and second frames to form an interior volume. The first and second frames are configured for flow of a liquid between them via the membrane. The membrane is configured to transport the liquid between the first and second frames and to provide for air flow through the membrane for evaporative cooling.

In one embodiment, the unit has a rounded square cross-sectional shape. In another embodiment, the unit has a diamond-shaped cross-sectional shape.

### BRIEF DESCRIPTION OF THE DRAWINGS

FIG. 1A is a front sectional view of a rounded square shape evaporative cooling unit.

FIG. 1B is a side sectional view of the rounded square shape evaporative cooling unit.

FIG. 2 is a diagram of a water recirculation system for an evaporative cooling unit.

FIGS. 3A-3D are graphs of a pressure drop and cooling effectiveness of an isolation cylindrical evaporative cooler based upon modeling data.

FIGS. 4A-4B are diagrams of in-line and staggered arrangement of square panels.

FIG. 4C is a diagram of an arrangement of triangular panels in a hexagonal lattice.

FIG. 4D is a diagram illustrating flow channeling effect in an array of panels.

FIG. 4E is a diagram of an annular frustum design to mitigate flow channeling.

FIG. 4F is a diagram of panels arranged in series.

FIGS. 5A-5D are graphs of a pressure drop and cooling effectiveness of an in-line arrangement of cylindrical evaporative coolers based upon modeling data.

FIG. 6A is a front sectional view of a diamond-shaped evaporative cooling unit.

FIG. 6B is a side sectional view of the diamond-shaped evaporative cooling unit.

FIG. 6C is a perspective view of the diamond-shaped evaporative cooling unit.

FIG. 7 is a diagram illustrating air flow through multiple stacked diamond-shaped evaporative cooling units.

FIG. 8A is a front view of an evaporative cooling unit with bifurcated water flow.

FIG. 8B is a side view of an evaporative cooling unit with bifurcated water flow.

FIG. 8C is a rear view of an evaporative cooling unit with bifurcated water flow.

FIG. 9 is a graph of the water pressure from modelling of the embodiment in FIGS. 8A-8C.

FIG. 10A is a side sectional view of a design of an air duct for the Examples.

FIG. 10B is a perspective view of the design of the air duct for the Examples.

### DETAILED DESCRIPTION

Embodiments include an evaporative cooler using a membrane having hollow fibers with porous walls, which provides enhanced evaporative cooling and reduced pressure drop. This construction includes an array of knitted fibers rolled into an annular circular cylinder, rounded square, or other shapes and potted at both ends to allow flow of liquid water through the fibers. One end of this annular cylinder is open for the passage of air and the other end is capped, which forces the air to flow through the fiber array to cool the incoming air. This construction could provide for ease of manufacturability compared to a folded design. This construction also provides for improvement of the panel performance by systematically increasing the length of the panel. Additionally, adding folds in the fiber array around the cylinder can also improve the performance due to increase in the surface area. This construction with hollow fibers with non-porous walls could also work as a heat exchanger. Using porous walled fibers can also work as a heat exchanger when the air is very humid.

### Rounded Square Shape Cooler

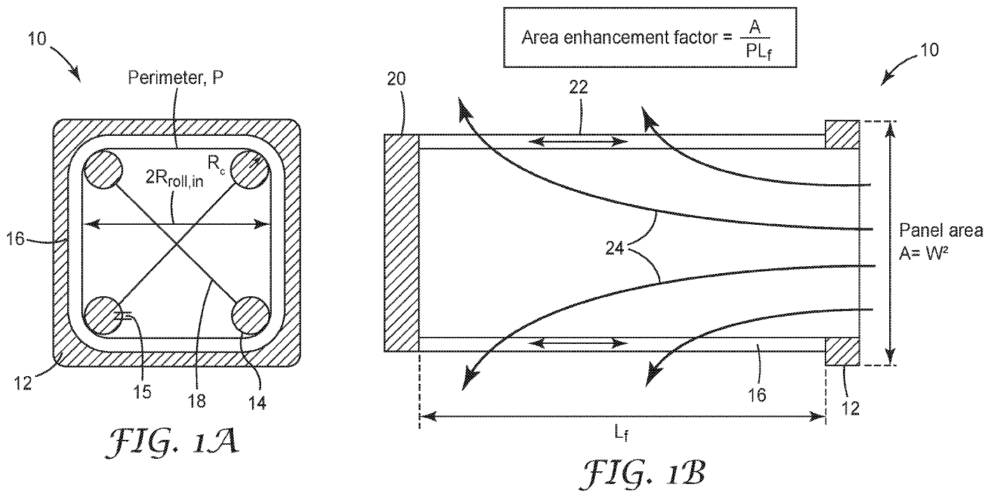

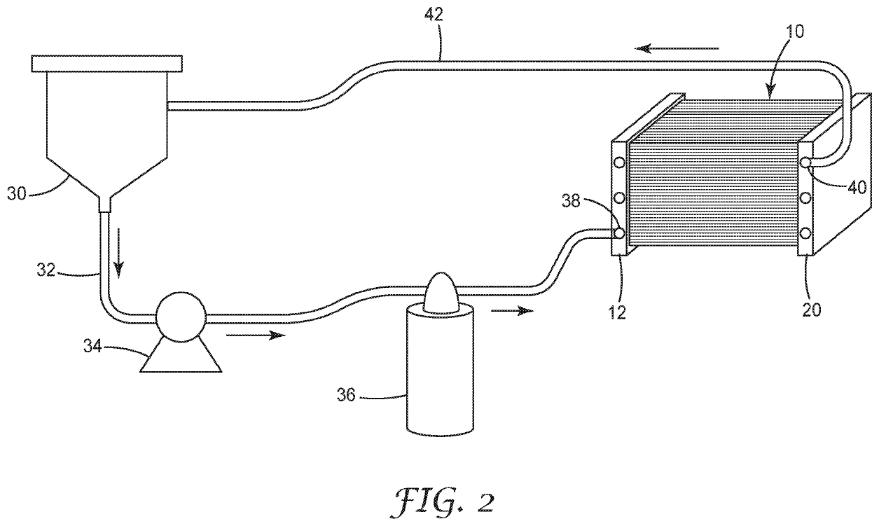

FIGS. 1A and 1B are front and side sectional views of an evaporative cooling unit 10 panel construction which includes a knitted fiber array using a rounded square shape, as an example. A perspective view of unit 10 is illustrated in FIG. 2. As shown in FIGS. 1A and 1B, this panel construction also works for any other cross-sectional shape as well. Unit 10 includes a front open frame 12, mechanical supports such as posts 14, a porous hollow fiber membrane 16, and a capped rear frame 20. Frame 12 is open in that frame 12 has an opening to allow for the passage or flow of air into unit 10. Frame 20 is capped in that frame 20 at least partially, and preferably completely, blocks the passage or flow of air in unit 10. As an optional alternative, unit 10 can include another membrane wrapped around another set of mechanical supports inside of membrane 16 and spaced apart from it. Unit 10 can be portable unit or non-portable.

A liquid such as water flows (22) between front frame 12 and rear frame 20. An air stream or air flow (24) from front frame 12 is forced by rear frame 20 through the fibers of membrane 16 to cool the air. Alternatively, air can flow in the other direction from outside unit 10 to the interior volume. Unit 10 preferably has no core, such that the interior volume is open between the frames, for more effective air flow through the interior volume. The air can be induced into a radial flow through the fibers of membrane 16. Frame 12 can be mounted in a horizontal direction in an air duct, and have mechanical structures for attachment to the air duct, with a fan to pull air from outside through membrane 16.

Posts 14 extend between and are coupled to frames 12 and 20, either directly or through other mechanical structures. Posts 14 can have optional perforations such as perforation 15. Only a single perforation 15 is shown for illustrative purposes: the posts have multiple perforations while still maintaining the mechanical stability of the posts. The perforations can provide for air flow through the posts. Posts 14 can be connected to one another to provide more support. For example, posts 14 can include an optional cross brace 18 located between frames 12 and 20, such as at a midpoint between the frames or other location. Cross brace 18, or other mechanical connection between posts 14, can divert the air flow through the interior volume of unit 10. One of the standoff posts can optionally be used as a pipe to facilitate the servicing and installation of the unit.

Posts 14 can have a circular cross-sectional shape, as shown, or other shapes such as the following alternatives and options. The posts can be a round corner rectangular bar, for example 0.75 inch×0.25 inch where each corner is radiused with a 0.125 inch radius and set at a 45° angle to the circumference for a square. The posts can be a folded post, where a 1.5 inch×0.125 inch piece of material is folded such that the cross section becomes 0.75 inch×0.25 inch. A post can be a corner post that is a 0.5 inch×0.5 inch×0.125 inch angle iron “L” shaped piece. One or more of the posts can be a hollow pipe to facilitate all of the water connections on one end (frame), for example.

Posts 14 are preferably constructed of ABS plastic. Alternatively, the posts can be formed from stainless steel, aluminum, or fiberglass. Frames 12 and 20 are preferably constructed of ABS plastic. Alternatively, the frames can be formed from PVC, styrene, polycarbonate, or metal(s). Materials of unit 10 can optionally have a Flame Retardant (FR) rating.

Membrane 16 (e.g., a knitted fiber mat) extends around the four posts 14 (e.g., wrapped around) to form an interior volume and can be mechanically held in place between posts 14 and the frames, as illustrated in FIG. 1A, or between an inner and outer frame assembly. Membrane 16 preferably forms a continuous loop around posts 14, as shown in FIG. 1A, to create the interior volume: alternatively, membrane 16 can form a discontinuous loop around the posts. The hollow fibers in membrane 16 are potted at the two ends of the frame. For example, the fibers of membrane 16 can be held in an epoxy in the frame with open ends of the hollow fibers to receive water or other liquid. As another example, the ends of the fibers in membrane 16 can be held by an adhesive, the adhesive can then be cut to open the ends of the fibers, and an end plate can be fixed over the open ends of the fibers. Alternatively, unit 10 can have a frame construction where the framework supports the open end of the hollow fibers, which are then attached to an air handler unit in a system that has water channels for use in circulating the water through the hollow fiber membrane.

Membrane 16 can include multiple layers, for example 27-33 layers wrapped around posts 14. Alternatively, a length of membrane 16 (L_{f}) can be increased to reduce the number of layers. The membrane is hydrophobic (at least on the inside) for water. Air flows from the front of the panel and through the fibers where evaporation cools the air. The air flow velocity through the fibers is reduced due to enhanced surface area. The following are exemplary parameters for the hollow fiber membrane: a pore size of 0.01-0.2 microns and preferred of 0.03-0.04 microns: a porosity of 25%-80%: a wall thickness (single layer) of 15-75 microns and preferred of 25-50 microns; and a knitting density of 20-60 fibers per inch and preferred of 35-53 fibers per inch. An example of a hollow fiber membrane is disclosed in U.S. Pat. No. 9,541,302. Examples of hollow fiber membranes are also included in the following products: the LIQUI-CEL MM Series Membrane Contactor from 3M Company (product ID B5005009013) and the LIQUI-CEL SP Series Membrane Contactor Cartridge from 3M Company (product ID B5005009016).

FIG. 2 is a diagram of a water recirculation system for evaporative cooling unit 10. A water tank 30 provides water on an intake line 32 to a pump 34, which circulates the water through a water filter 36 to an inlet 38 in frame 12. An outlet 40 on frame 20 provides the water to a water return line 42 back to water tank 30. Alternatively, the water can flow in the other direction with frame 20 receiving the water. Optionally, one frame can include both the inlet and the outlet. The water can have a particular type of quality. The water recirculation system can optionally include an anode/cathode feature to control mineral buildup within the water loop.

For the construction shown in FIGS. 1A and 1B, the velocity U of the incoming air is greatly reduced by the enhancement of the area, and the local air velocity going across the fibers is approximately given by

$${U}_{l} \approx U \frac{A}{{PL}_{f}} , \qquad ( 1 )$$

where A is the panel frontal area of the construction, P is the approximate perimeter of the fiber mat and L_{f} is the length of the exposed fiber. The frontal area for the panel described herein is W², W being the length of the side as shown in FIG. 1B. The local velocity U₁ can be systematically reduced by increasing L_{f}. The effect of other design variables, such as open area post size, can be obtained from numerical simulations or experiments. The velocity reduction factor λ is defined as ratio of the mean local velocity passing through the fiber stack and the air velocity incoming on the frontal face of the panel and is mathematically given by:

$$λ = \frac{{U}_{l}}{U} \approx \frac{A}{{PL}_{f}} . \qquad ( 2 )$$

The value of λ is the characteristic feature of the design and is fixed for a given construction. The local velocity of air passing through the fibers is approximately given by U₁=λU. The effectiveness of the panel (hollow fiber membrane) should increase and the pressure drop decrease with decreasing value of λ. The cooling effectiveness ϵ is given by:

$$ϵ = \frac{{T}_{i n} - {T}_{out}}{{T}_{i n} - {T}_{wb}} , \qquad ( 3 )$$

where Tᵢₙ is the inlet air temperature, Tₒᵤₜ is the outlet air temperature and T_{wb} is the wet bulb temperature at the inlet air temperature and relative humidity. The value of ϵ quantifies the fraction of maximum available evaporative cooling from the cooling device. The flow of air through the panels can also be in the reverse direction to the one shown in FIG. 1B.

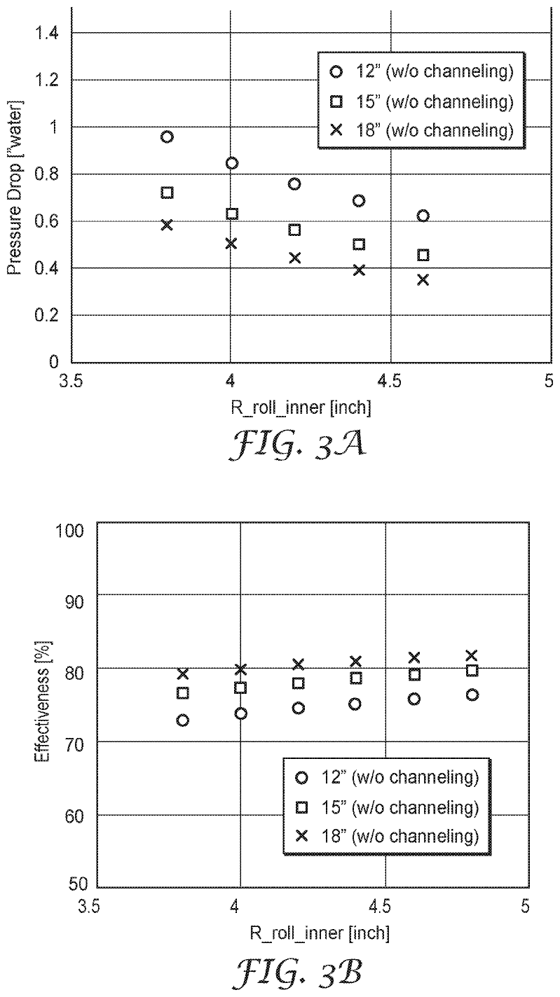

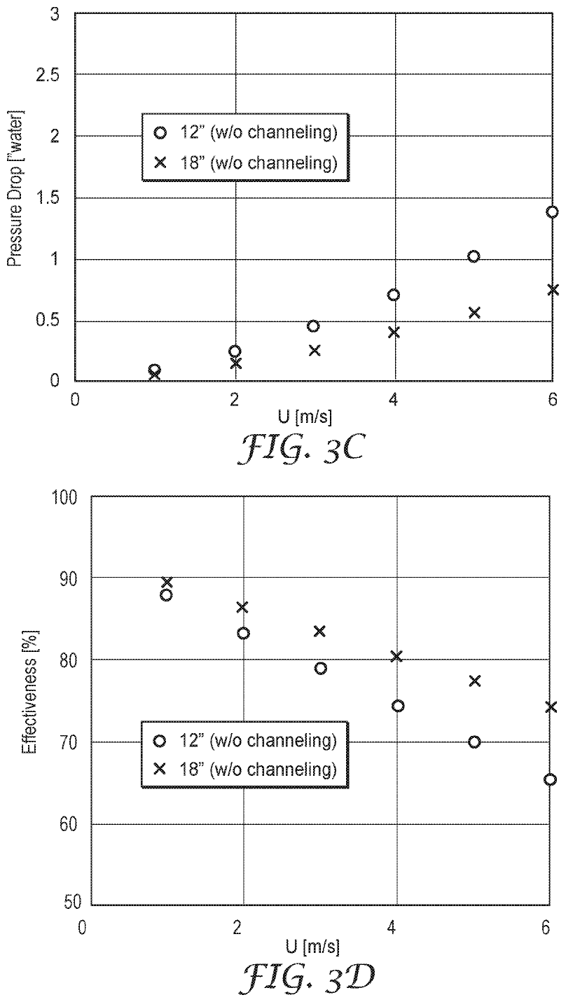

The effect of R_{roll,in} on the air-side pressure drop is obtained using computational fluid dynamics (CFD) calculations, and its effect on the cooling effectiveness is obtained from a numerical simulation tool. The pressure drop of the panel construction described herein at U=3.5 m/s for different values of R_{roll,in} and L_{f} is shown in FIG. 3A. The extent of the panel W was fixed to 12″ and R_{c}=0.5″ for this design. The pressure drop reduces with increasing R_{roll,in} for a given L_{f} because of reduction in λ≈0.25R_{roll,in}L_{f}⁻¹. Similarly, for a given R_{roll,in} the pressure drop reduces by increasing the length of the module L_{f}. The cooling effectiveness of a single panel as a function of R_{roll,in} and L_{f} is also shown in FIG. 3B. The effectiveness increases with reduced R_{roll,in} and increased L_{f} due to the associated reduction in λ or equivalently reduction in the local air velocity passing across the fibers U₁.

The pressure-drop is shown as a function of the face velocity U in FIG. 3C. The pressure drop is a quadratic function of U as expected for a porous media formed by a set of cylinders. Therefore, the difference in the pressure drop between the two designs is more pronounced at higher velocities. The effectiveness is also shown for the two designs in FIG. 3D which reduces with increasing velocity. The slope (dϵ/dU) is more gentle for the design with longer L_{f} since that design has a lower λ (or lower air velocity flowing across the fibers). The appropriate fiber length can be chosen based on the cooling requirement, the pressure drop constraints and the available space for the panel.

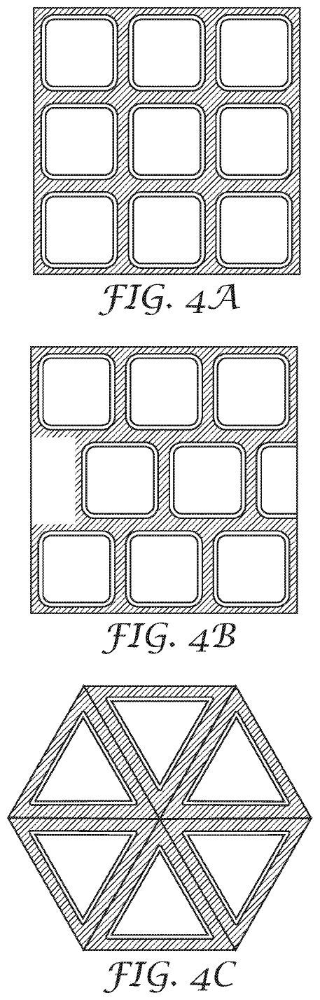

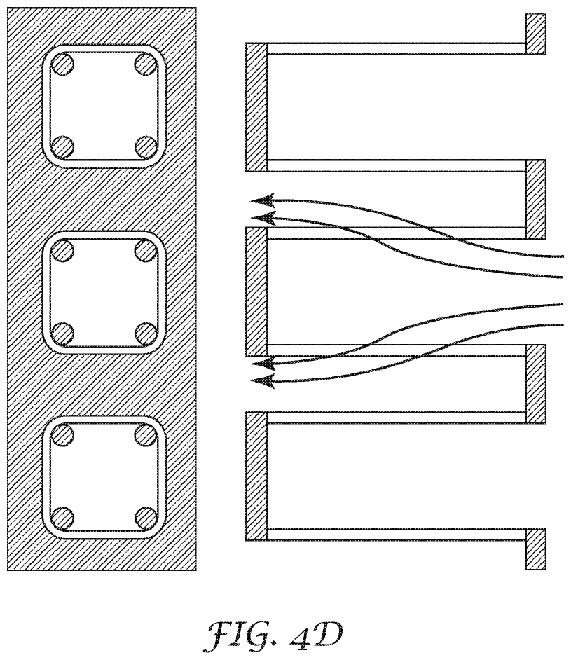

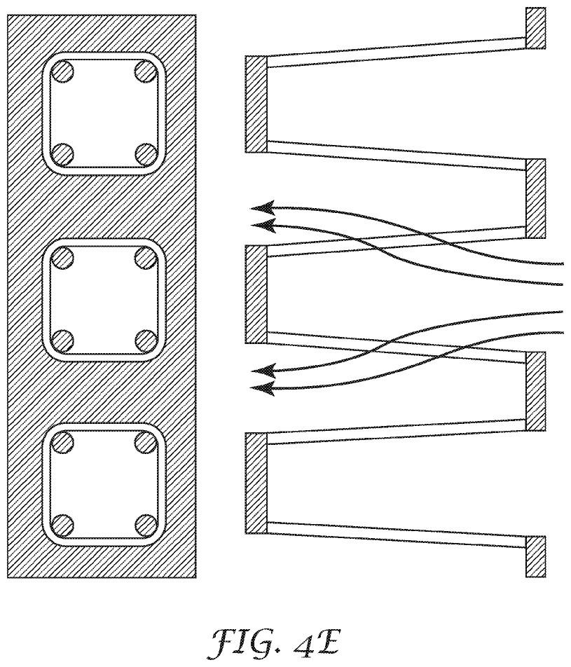

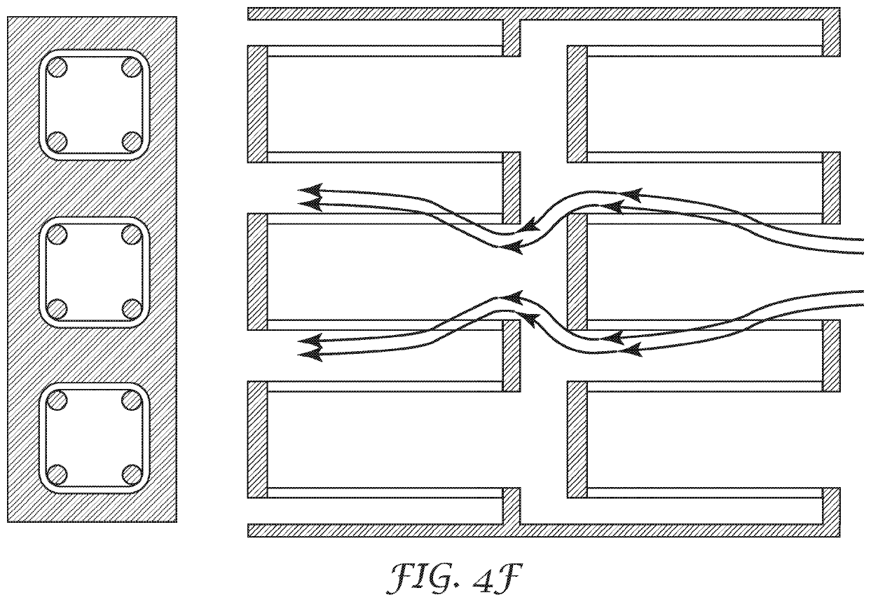

In certain scenarios, multiple panels can be used together to handle larger cooling loads. Different panel arrangements are shown in FIGS. 4A-4F. FIGS. 4A-4B are diagrams of in-line and staggered arrangement of square panels. FIG. 4C is a diagram of an arrangement of triangular panels in a hexagonal lattice. FIG. 4D is a diagram illustrating air flow channeling effect in an array of panels. FIG. 4E is a diagram of an annular frustum design to mitigate flow channeling. FIG. 4F is a diagram of panels arranged in series. The modular arrangements shown in FIGS. 4A-4F can provide for operations leading to water savings.

In the square panel construction, the panel performance is demonstrated in a collection of panels using the in-line panel arrangement shown in FIG. 4A. Such a panel arrangement can be used in large evaporative coolers or in air-handler units which typically have a duct with rectangular cross section. The fluid flow of a collection of panels changes slightly from the isolated panel construction as shown in FIG. 4D. The fluid travels through the annular region between the adjacent panels on the outlet side of the set-of-panels. This flow-channeling effect has an additional pressure drop which is absent in the isolated panel construction. Panels can also be arranged in series to obtain higher evaporative cooling in the outlet air.

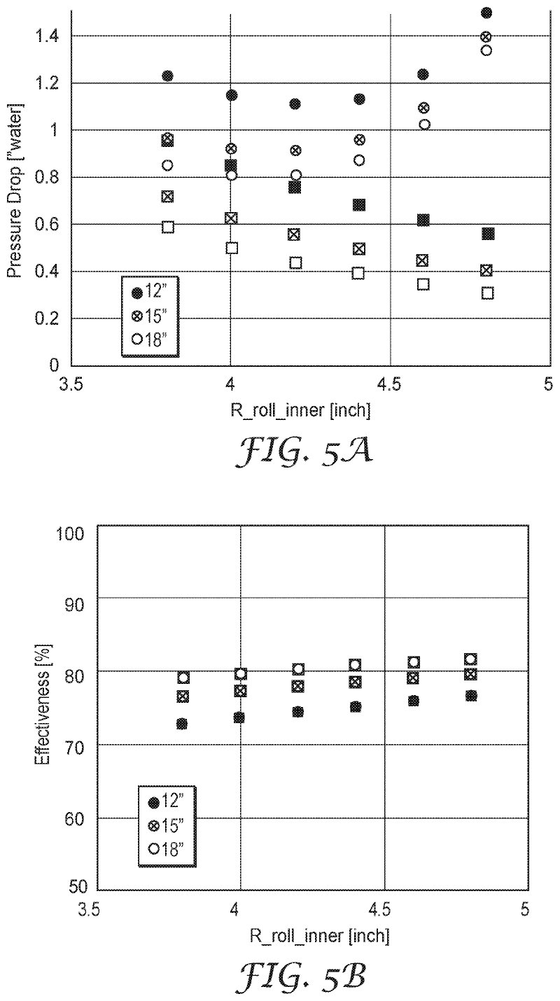

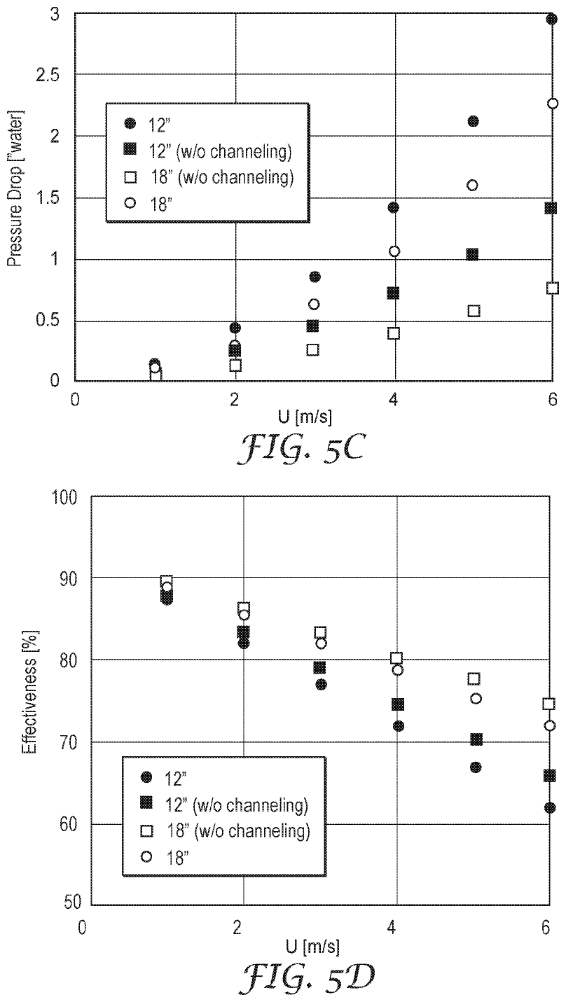

The pressure drop for the collection of panels as a function of R_{roll,in} is shown in FIG. 5A (o symbols) for the same panel design discussed with respect to FIGS. 3A-3D.

In FIGS. 5A-5D, square symbols are a case with no-channeling and circles are ones with channeling effect. FIG. 5A also has the corresponding pressure-drop values for an isolated panel (x symbol). The square symbols are isolated panel results. The flow channeling is responsible for the larger pressure drop numbers compared to the isolated panel result. The pressure drop reduces with increasing R_{roll,in} in for small values of R_{roll,in} until R_{roll,in}˜4.2″ for this design as expected from the isolated panel result. However, the pressure drop starts increasing with further increasing R_{roll,in} in because of the flow channeling effect. The pressure drop changes with R_{roll,in} is small near this optimal value of about R_{roll,in}˜4.2″ wherein the channeling effect is small and λ is also sufficiently small. The optimal 4.2″ value is only for the construction described herein where W=12″. The simulation results show that the effectiveness is not significantly affected by the channeling effect and should remain comparable to the isolated panel values. This effectiveness should also hold in practice as evaporation process is a local process that happens near the walls of individual fibers. The local fluid flow should affect the overall evaporation efficiency. The possibility of back flow into the array of fibers due to turbulence in the flow-channeling zone is in general small.

FIGS. 5A and 5B show, respectively, the pressure drop and cooling effectiveness of an in-line arrangement of cylindrical evaporative coolers as a function of the R_{roll,inner} at U=3.5 m/s (filled o symbols), and pressure drop and cooling effectiveness of an in-line arrangement of cylindrical evaporative coolers as a function of U with R_{roll,in}=4.2″ (o symbols). The corresponding values of pressure drop and effectiveness for an isolated panel are also shown (x symbols). In all designs R_{c}=0.5″.

FIGS. 5C and 5D also show the pressure drop and effectiveness, respectively, as a function of U (o symbols). The pressure drop for the isolated panel is also shown in the FIG. 5C for comparison. The flow channeling effect leads to the higher numbers for the in-line arrangement of panels compared to the isolated panel. The slight reduction in the effectiveness is due to small changes in the flow field that will occur near the ends of the fiber. The flow channeling effects can be mitigated through an annular frustum type construction as shown in FIG. 4E, where the mean gap of the channel is increased. Alternatively, a structure (e.g., a cone) can be located within the interior volume, such as against the capped end with the cone extending into the interior volume, in order to disrupt or otherwise change the air flow.

### Diamond-Shaped Cooler

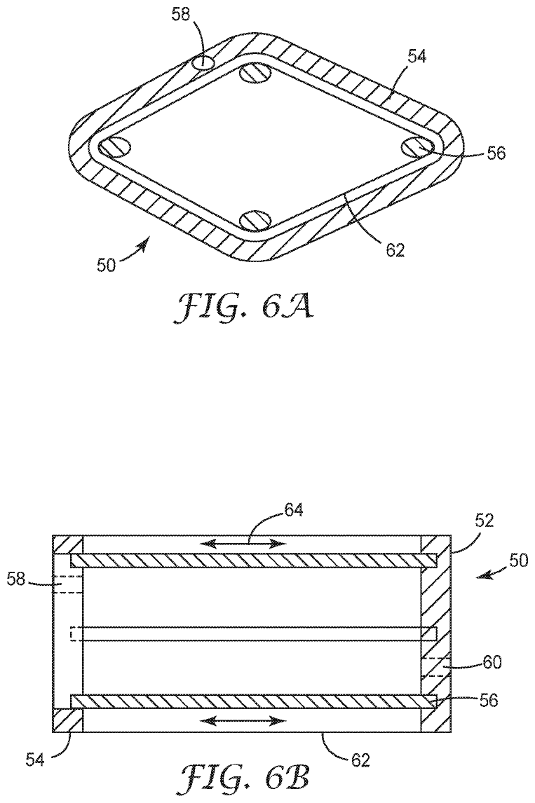

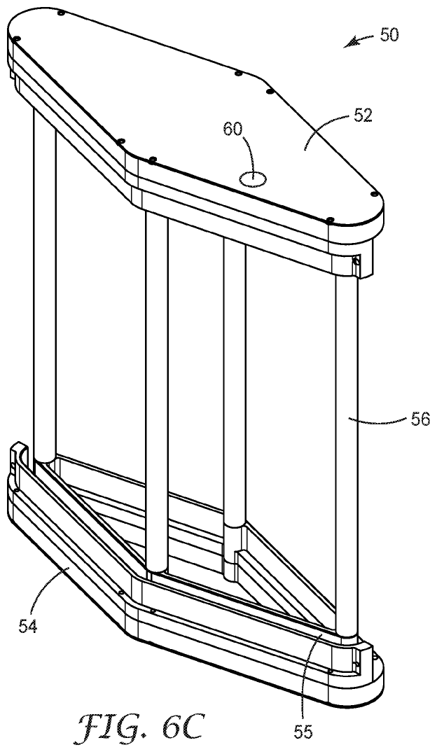

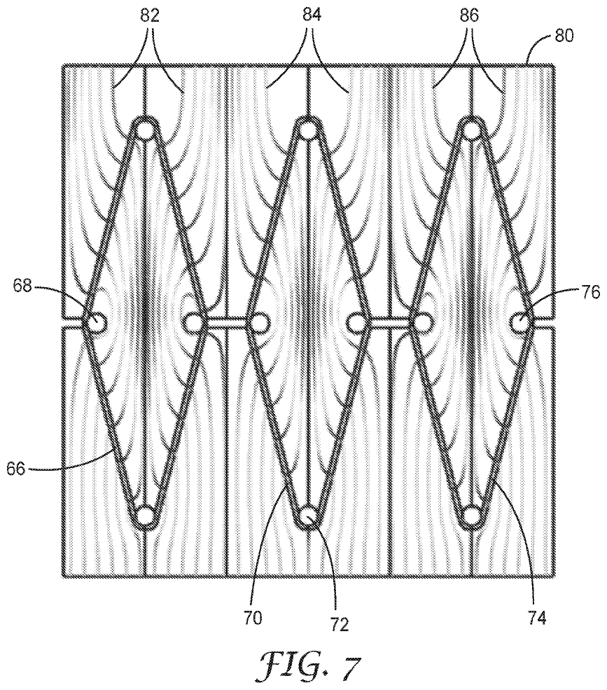

FIGS. 6A, 6B, and 6C are, respectively, front sectional, side sectional, and perspective views of a diamond-shaped evaporative cooling unit 50 which includes a knitted fiber array. As shown in FIGS. 6A-6C, unit 50 includes an open frame 54, mechanical supports such as posts 56, a porous hollow fiber membrane 62, and a capped frame 52. As an optional alternative, unit 50 can include another membrane wrapped around another set of mechanical supports inside of membrane 62 and spaced apart from it. Unit 50 can be portable unit or non-portable. The frames can have a groove, such as groove 55 shown in FIG. 6C, for holding an edge of membrane 62. FIG. 6C is shown without membrane 62 for illustrative purposes.

As shown in FIG. 6A, unit 50 has a diamond-shaped or rhombus-like cross-sectional shape. This exemplary diamond shape has a first pair of sides substantially parallel with one another and a second pair of sides substantially parallel with one another. The first pair of sides are substantially non-parallel with the second pair of sides. In particular, the cross-sectional shape includes an acute angle between two sides (e.g., angle at post 56) of 20° or 30° or greater and less than 90°. The opposing acute angles are typically the same but could be different and still within the recited range of 20° up to but less than 90°. The sides can have equal lengths, as represented in FIG. 6A, or one or more of the sides can have unequal lengths. If at least some of the sides have different lengths, then the opposing acute angles may be different.

Unit 50 can have ports 58 and 60 for recirculation of water or other liquid through membrane 62. In the water recirculation system of FIG. 2, for example, port 58 can be coupled to intake line 32 and port 60 can be coupled to return line 42 for circulation of water or other liquid through membrane 62. Alternatively, one of the frames can have both ports for circulation of the water or other liquid through the membrane and opposite frame.

The following are exemplary dimensions for unit 50: a length between the frames of 19⅝ inches: a width between opposing posts of 17 inches; and a height between opposing posts of 6.25 inches.

A liquid such as water flows (64) between frame 54 and frame 52. An air stream or air flow is forced through membrane 62, as described below, to cool the air. Unit 50 preferably has no core, such that the interior volume formed by membrane 62 is open between the frames, for more effective air flow through the interior volume.

Posts 56 extend between and are coupled to frames 54 and 52, either directly or through other mechanical structures. Posts 56 can have optional perforations such as perforation 15 shown in FIG. 1A. The perforations can provide for air flow through the posts. Posts 56 can be connected to one another to provide more support, for example using a cross brace such as optional cross brace 18 shown in FIG. 1A. One of the standoff posts can optionally be used as a pipe to facilitate the servicing and installation of the unit. Posts 56 can have the exemplary shapes and dimensions as described above with respect to the embodiment shown in FIGS. 1A and 1B. Posts 56 and frames 54 and 52 can be constructed of the exemplary materials as described above with respect to the embodiment shown in FIGS. 1A and 1B.

Membrane 62 (e.g., a knitted fiber mat) extends around the four posts 56 (e.g., wrapped around) to form an interior volume and can be mechanically held in place between posts 56 and the frames, as illustrated in FIG. 6A, or between an inner and outer frame assembly. Membrane 62 preferably forms a continuous loop around posts 56, as shown in FIG. 6A, to create the interior volume; alternatively, membrane 62 can form a discontinuous loop around the posts. The hollow fibers in membrane 62 are potted at the two ends of the frame in groove 55 or in other ways. For example, the fibers of membrane 62 can be held in an epoxy in the frame with open ends of the hollow fibers to receive water or other liquid. As another example, the ends of the fibers in membrane 62 can be held by an adhesive, the adhesive can then be cut to open the ends of the fibers, and an end plate can be fixed over the open ends of the fibers. Alternatively, unit 50 can have a frame construction where the framework supports the open end of the hollow fibers, which are then attached to an air handler unit in a system that has water channels for use in circulating the water through the hollow fiber membrane.

Membrane 62 can include multiple layers, for example 27-33 layers wrapped around posts 56. Alternatively, a length of membrane 62 can be increased to reduce the number of layers. The membrane is hydrophobic (at least on the inside) for water. Air flows through the fibers where evaporation cools the air. The air flow velocity through the fibers is reduced due to enhanced surface area. The following are exemplary parameters for the hollow fiber membrane; a pore size of 0.01-0.2 microns and preferred of 0.03-0.04 microns; a porosity of 25%-80%; a wall thickness (single layer) of 15-75 microns and preferred of 25-50 microns; and a knitting density of 20-60 fibers per inch and preferred of 35-53 fibers per inch. An example of a hollow fiber membrane is disclosed in U.S. Pat. No. 9,541,302. Examples of hollow fiber membranes are also included in the following products: the LIQUI-CEL MM Series Membrane Contactor from 3M Company (product ID B5005009013) and the LIQUI-CEL SP Series Membrane Contactor Cartridge from 3M Company (product ID B5005009016).

FIG. 7 is a diagram illustrating air flow through multiple stacked diamond-shaped evaporative cooling units. This example includes three diamond-shaped cooling units: a unit 66 having posts 68; a unit 70 having posts 72; and a unit 74 having posts 76. The cooling units 66, 70, and 74 can be held within a frame 80. Two of the posts between units 66 and 70, and between units 70 and 74, can be coupled to one another as shown. One of the posts in unit 66 and one in unit 74 can be coupled to frame 80 as shown. The cooling units 66, 70, and 74 can be constructed as described above with respect to cooling unit 50. The air flow is illustrated by lines 82 for the air flow through unit 66, lines 84 for the air flow through unit 70, and lines 86 for the air flow through unit 74. As shown, the air flows from outside of the cooling units through the membrane and the interior volume and then back outside the cooling units.

The multiple stacked diamond-shaped evaporative cooling units can optionally have a filler material in the “dead space” region at the outlet air side. This filler material would help prevent eddies from developing in the flow field and allow for more of the humidified air to reach data servers, for example, improving efficiency of this cross-flow design. The filler material could be located between post 68 and frame 80, between post 76 and frame 80, between the posts coupled together between units 66 and 70, and between the posts coupled together between units 70 and 74.

### Bifurcated Water Flow

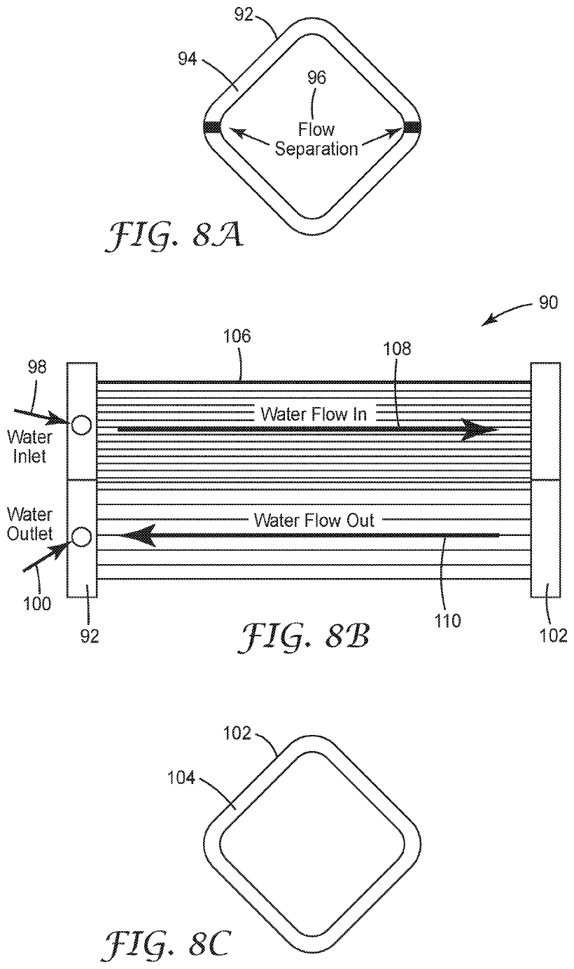

FIGS. 8A, 8B, and 8C are front, side, and rear views, respectively, of an evaporative cooling unit 90 with bifurcated water flow. Unit 90 includes a front frame 92 having a channel 94 and flow separation elements 96 that divide channel 94 into two channels and prevent flow of water between the two channels. A rear frame 102 for unit 90 includes a continuous channel 104. Channels 94 and 104 can be formed by machining the frames to create a groove, and flow separation elements 96 can be formed by not machining the corners such that those portions of the frames block water flow. A porous hollow fiber membrane 106 with hollow fibers is located between front frame 92 and rear frame 102. In use, front frame 92 includes a water inlet 98 for water flow in (108) through the hollow fibers in membrane 106 to rear frame 102. The water is forced under pressure through channel 104 in rear frame 102 for water flow out (110) to a water outlet 100 in front frame 92.

In this embodiment, the water inlet and water outlet are thus located on the same side of unit 90 in frame 92. This feature bifurcates the water channel and sends the water down two contiguous faces of the unit and back through the other two contiguous faces. In unit 90, the water flows to the right in the top two surfaces and returns to the left in the bottom two surfaces. Alternatively, unit 90 can include water inlets and outlets on both frames 92 and 102 to bifurcate the water flow on both ends. This feature can provide advantages for the end-use customer including ease of assembly and lower air pressure drop during operation. Also, in this embodiment there is no need to use a pipe as one of the posts to transport water between the ends (frames) of the unit.

Unit 90 can have a similar configuration, features, and materials as unit 10 shown in FIGS. 1A and 1B aside from the bifurcated water flow feature. In particular, frame 92 can be an open frame, and frame 102 can be a capped frame. Alternatively, frame 102 can include the inlet, outlet, and flow separation elements with frame 92 having the continuous channel. Frame 92 can be coupled to frame 102 with mechanical supports, such as posts, with membrane 106 wrapped around the posts. Membrane 106 can be held in the frames with an adhesive and with open ends of the fibers in membrane 106 being in fluid communication the channels in the frames. Membrane 106 can have the properties as described above for unit 10. In use, inlet 98 can be coupled to intake line 32 (see FIG. 2), and outlet 100 can be coupled to return line 42.

The bifurcated water flow feature can also be incorporated into diamond-shaped evaporative cooling unit 50 shown in FIGS. 6A-6C.

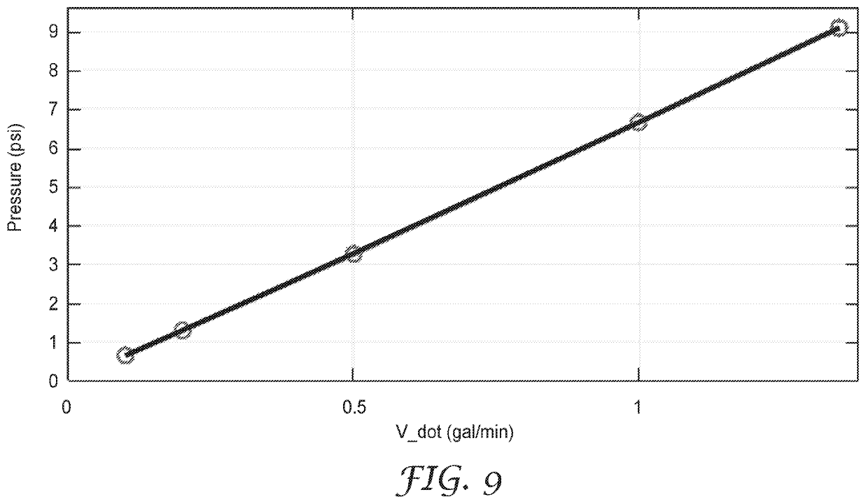

Modeling has shown that this bifurcated water flow design does not negatively affect cooling efficiency or air pressure drop during operation. The only noticeable change in the modeling was that the water pressure through the fibers should be upwards of four times as high as the design shown in FIGS. 1A and 1B at the same gallons per minute flow rate. This change results from the water travelling twice as far through half as many fiber openings. FIG. 9 is a graph of the water pressure from the modelling of this embodiment.

### EXAMPLES

These examples are merely for illustrative purposes only and are not meant to be limiting on the scope of the appended claims.

TABLE 1
Material

| Abbreviation | Description |
|---|---|
| HFPM | Hollow fiber porous membrane, 3M MEMBRANA |
| | Oxygenation Membrane Series X30-230 on a bobbin, ~30 |
| | micron wall thickness and an internal diameter of 230 |
| | microns, available from 3M Company, St. Paul, MN. |

TABLE 2
Air Handling Unit and Equipment

| Abbreviation | Description |
|---|---|
| Air blower | Terrabloom 10 inch Inline Duct Fan available from Amazon |
| Air temp/humidity | Digital Hygrometer/Thermometer model 4085, 03313-66, NIST Traceable, |
| sensor | TRACEABLE Products, Webster, TX. |
| Water pump | High-head enclosed motor PP centrifugal pump; 11.4 GPM/43.2 ft, 115 V, |
| | from Cole-Parmer |
| HF-35 water filter | 3M water filter, HF351.67 GPM flow rate, 1 micron nominal, from 3M |
| | company, St Paul, MN |
| Air pressure meter | Airdata multimeter ADM-880C, Shortridge Instruments, Inc, Scottsdale, AZ |
| Air velocity | VelociCalc, from TSI incorporated |
| sensor | |
| Water tank and | Plastic easy-drain tank, 10 gallon and stand, McMaster-Carr Supply |
| stand | Company |
| Water flow meter | Model A1Q9GMN025NA1 GPI water flow meter, from Great Plains |
| | Industries, Inc., Wichita, KS |
| Water pressure | 0 to 300 psi digital pressure gauge, SSI Technologies, Inc. |
| gauge | |
| Water temperature | Thermometer, Omega HH802U with K type thermocouple, Newark, |
| sensor | Chicago, IL |
| Hot air gun | 110 V/14.5 A Varitemp heat gun, model VT-750C, Master Appliance Corp, |
| | Racine, WI |

### Examples

### Construction of Evaporative Cooling Unit

FIGS. 1A and 1B show the evaporative cooling unit. This was constructed by assembling 4 posts (15.5 inch long, ¾ inch diameter—ABS from International Plastics) into bottom and top end frames (7.5 inch inner opening—ABS). An 18.5 inch-wide array of knitted HFPM was wound around the support posts and held in place with a bead of adhesive at the top and bottom edge. The evaporative cooling unit was built with 33 wraps of knitted HFPM. Next, an outer frame (ABS) was attached around both top and bottom fames and potted in place with adhesive. After the adhesive was set, an end cap was attached to each end of the inner/outer frame assembly to form a ¼ inch water channel that communicated with the HFPM. Tapped ports (¼ inch NPT) were made on the top and bottom of the end caps to facilitate water flow to and from the evaporative cooling unit. A ⅛ inch aluminum cap was attached to the downstream side frame of the evaporative cooling unit closing off this end of the unit.

### Testing

### Equipment

To characterize the performance of evaporative cooling unit, an air handling unit consisting of an air duct with enclosure, closed loop water recirculation system, and measurement equipment was assembled.

### Air Duct, Enclosure, and Mounting Backplane

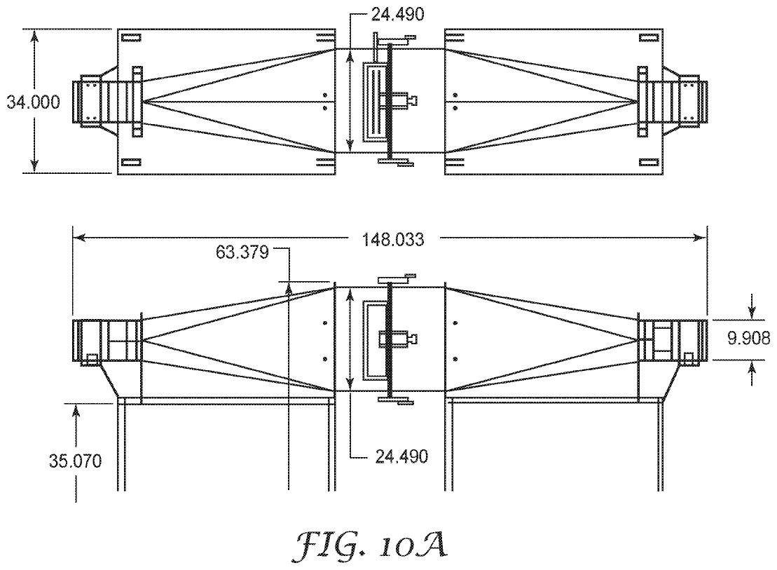

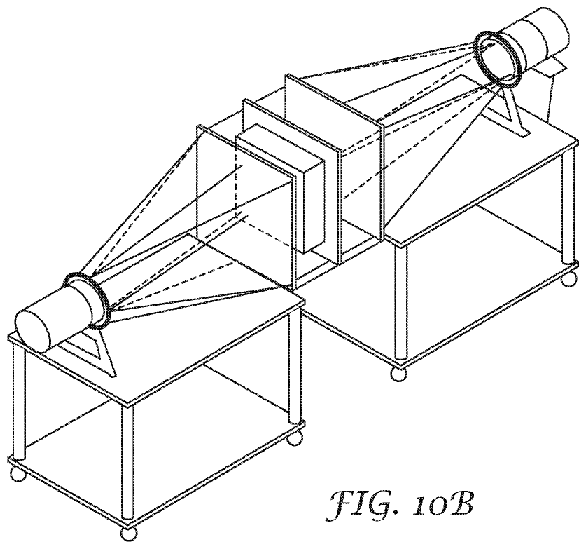

The design for the air duct is shown in FIGS. 10A and 10B in side sectional and perspective views, respectively. A plexiglass enclosure with a backplane for mounting the evaporative cooling unit was built to attach to the inlet side of the air duct. The evaporative cooling unit was attached with the open side aligned to a cut-out hole of the backplane to allow for airflow into the unit.

### Air Circulation/Heating Equipment and Air Measurement Devices

To enable air movement, two air blowers were attached to the outlet side of the end of the air duct. To provide heated air, a hot air gun was inserted into the inlet side of the air duct. The gun was operated on the high setting. Air temperature and humidity sensors were installed at the inlet and outlet of the air duct. An air pressure meter was also installed to measure the pressure drop across the evaporative cooling unit.

### Closed Loop Water Recirculation System-FIG. 2

A water recirculation system was installed to cycle water through the evaporative cooling unit. A 10-gallon plastic water tank with stand (30) was used to hold the water. The gravity feed under the tank was plumbed with plastic tubing to deliver water to the water pump (34). The pump sent the water through the inlet water flow meter, water filter (36), water pressure gauge, and finally into the water inlet of the evaporative cooling unit (10). Water travelled through the HFPM to the outlet side of the evaporative cooling unit. Plastic tubing was attached and connected to an outlet water pressure gauge, outlet water flow meter, and finally connected to the side of the water tank. This formed a closed system to recirculate water through the system. A water temperature sensor with K-type thermocouple was used to monitor the temperature of water in the tank.

### Testing Conditions and Results

Water was recirculated through the 33 layer evaporative cooling unit at 1 gallon/minute. Inlet water pressure was 8.5 psi and outlet water pressure 3 psi. The water temperature in the tank was 74.9 deg F. The blowers were turned on to setting 6. The air velocity was measured and a volumetric flow of 715 ft³/min was calculated. An air pressure of 0.78 inches of water was measured. The inlet and outlet air temperatures and % relative humidity values were measured as shown in Table 3. The wet bulb temperature was determined to be 68 deg F. The cooling effectiveness was calculated according to equation 3, expressed as a percentage.

TABLE 3
Results - Measured Air Properties

| Inlet Air Temp | Inlet Air | Outlet Air | Outlet Air | % Cooling |
|---|---|---|---|---|
| (deg F.) | % RH | Temp (deg F.) | % RH | Effectiveness |
| 84 | 42.4 | 72.5 | 80.9 | 71.9 |

1. A unit for use in evaporative cooling, comprising:
a first capped frame;
a second open frame opposite the first frame;
a plurality of mechanical supports between and coupled to the first frame and the second frame; and
a porous hollow fiber membrane extending around the mechanical supports between the first frame and the second frame to form an interior volume, and coupled to the first frame and the second frame,
wherein the first and second frames are configured for flow of a liquid between the first and second frames via the membrane, and the membrane is configured to transport the liquid between the first and second frames and to provide for air flow through the membrane for evaporative cooling.

2. The unit of claim 1, wherein the plurality of mechanical supports comprise posts.

3. The unit of claim 2, wherein the plurality of posts form a square shape with rounded corners.

4. The unit of claim 2, wherein the plurality of posts form a polygonal shape.

5. The unit of claim 2, wherein one or more of the posts are perforated.

6. The unit of claim 2, wherein the posts are composed of a plastic material.

7. The unit of claim 2, wherein one of the posts comprises a pipe for transporting the liquid.

8. The unit of claim 1, wherein the membrane forms a continuous loop around the posts.

9. The unit of claim 1, wherein the membrane has a plurality of layers.

10-11. (canceled)

12. The unit of claim 1, further comprising a pump coupled to the first frame and the second frame for circulating the liquid through the membrane.

13. The unit of claim 12, further comprising a filter coupled to the pump.

14-15. (canceled)

16. The unit of claim 1, wherein the interior volume is open between the first frame and the second frame.

17. (canceled)

18. The unit of claim 1, wherein ends of fibers in the membrane are held by an adhesive with the ends being open.

19. (canceled)

20. The unit of claim 1, wherein the first or second frame includes an inlet, an outlet, a first channel for the inlet, a second channel for the outlet, and flow separation elements between the first and second channels.

21. The unit of claim 20, wherein the first or second frame includes a continuous channel.

22. The unit of claim 1, wherein the membrane has a pore size of 0.01-0.2 microns.

23. The unit of claim 1, wherein the membrane has a porosity of 25%-80%.

24. The unit of claim 1, wherein the membrane has a wall thickness of 15-75 microns.

25. The unit of claim 1, wherein the membrane has a knitting density of 35-53 fibers per inch.

26. A unit for use in evaporative cooling, comprising:
a first frame;
a second frame opposite the first frame;
a plurality of mechanical supports between and coupled to the first frame and the second frame; and
a porous hollow fiber membrane extending around the mechanical supports between the first frame and the second frame to form an interior volume, and coupled to the first frame and the second frame,
wherein the first and second frames are configured for flow of a liquid between the first and second frames via the membrane, and the membrane is configured to transport the liquid between the first and second frames and to provide for air flow through the membrane for evaporative cooling,
wherein the first and second frames with the mechanical supports form a diamond-shaped cross-sectional shape of the unit.

27-43. (canceled)
